(19) United States
(12) Patent Application Publication
(10) Pub. No.: US 2025/0385079 A1
(43) Pub. Date: Dec. 18, 2025

(54) Heated Process Kit for Substrate Processing

(71) Applicant: Applied Materials, Inc., Santa Clara, CA (US)

(72) Inventors: Prashant AGARWAL, Singapore (SG); Kang Zhang, Singapore (SG); Ananthkrishna Jupudi, Singapore (SG); Sarath Babu, Singapore (SG); Muhammad Hafeez Lee Bin Yusof Lee, Singapore (SG)

(21) Appl. No.: 18/745,494

(22) Filed: Jun. 17, 2024

(51) Int. Cl. H01J 37/32; H01J 37/244

(52) U.S. Cl. CPC H01J 37/32477; H01J 37/244; H01J 37/3244; H01J 37/32467; H01J 37/32522; H01J 37/32651; H01J 2237/24585; H01J 2237/335

(57) ABSTRACT

Methods and apparatus for substrate processing are provided that use a process kit for use in a process chamber, comprising: a top plate having a top side and a bottom side; a plurality of holes disposed on the bottom side; a channel extending from an outer portion of the top plate and coupled to the plurality of holes; at least one heater embedded in the top plate; and at least one temperature sensor embedded in the top plate, wherein a gas flow path extends from the channel, through the plurality of holes, and into an interior volume of the process chamber.

### FIELD

Embodiments of the present disclosure generally relate to substrate processing equipment and, more specifically, to process kits for use in substrate processing equipment.

### BACKGROUND

Process chambers configured to perform a preclean process can remove native oxide on metal contact pads of a substrate prior to physical vapor deposition (PVD) for depositing one or more barrier layers, e.g., titanium (Ti), copper (Cu), etc., on the substrate and to remove other materials. Preclean chambers, typically, use ion bombardment (induced by RF plasma) to remove the native oxide on the metal contact pads and other materials. For example, the preclean process can etch the native oxide and material from the substrate. The preclean process is configured to lower contact resistance between the metal contacts on the substrate to enhance performance and power consumption of integrated circuits on the substrate and to promote adhesion.

During the preclean process, atoms or molecules of the contaminants and/or substrate material are etched from the substrate and are, for the most part, pumped out of the chamber. However, some of the contaminant and/or etched material may be deposited on surfaces of the chamber.

Process kits are typically used to reduce or prevent deposition of contaminants and/or etched materials onto surfaces of the chamber. However, contaminants may build up over time on the process kits and flake off into particles of a size that may interfere with downstream substrate processing. Due to the accumulation of contaminants on the process kit, a process called pasting is often performed periodically on the process kit to deposit a layer of material over the process kit that functions to glue down, or paste, the contaminants or etched materials to the process kit. However, the pasting process requires additional downtime of the process chamber and reduces throughput of substrates.

Accordingly, the inventors have provided apparatus and methods that can reduce or avoid the buildup and flaking of contaminants on process kits, which can thereby reduce downtime and increase throughput.

### SUMMARY

Methods and apparatus for substrate processing are provided herein. In some embodiments, a process kit for use in a process chamber includes: a top plate having a top side and a bottom side; a plurality of holes disposed on the bottom side; a channel extending from an outer portion of the top plate and coupled to the plurality of holes; at least one heater embedded in the top plate; and at least one temperature sensor embedded in the top plate, wherein a gas flow path extends from the channel, through the plurality of holes, and into an interior volume of the process chamber.

In some embodiments, a process chamber includes: a chamber body having a sidewall, the chamber body partially defining an interior volume; a substrate support disposed in the interior volume; a process kit supported by the sidewall the process kit comprising: a top plate having a top side and a bottom side; a plurality of holes disposed on the bottom side; a channel extending from an outer portion of the top plate and coupled to the plurality of holes; at least one heater embedded in the top plate; and at least one temperature sensor embedded in the top plate, wherein a gas flow path extends from the channel, through the plurality of holes, and into the interior volume.

In some embodiments, a method of processing a substrate in a process chamber includes: actively heating a top plate of a process kit supported by sidewalls of a chamber body of the process chamber, the chamber body defining an interior volume; flowing a plasma forming gas through a channel and a plurality of holes in the top plate into the interior volume; and generating plasma from the plasma forming gas above a substrate support in the interior volume.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a schematic side view of a process chamber in accordance with at least some embodiments of the present disclosure.

FIG. 1B is a detailed partial view of a portion A of FIG. 1A.

FIG. 2 is a schematic top view of an upper shield of a process kit in accordance with some embodiments of the present disclosure.

FIG. 3 is a schematic top view of an upper shield of a process kit in accordance with some embodiments of the present disclosure.

FIG. 4 is a flow chart depicting a method in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of process kits and methods for use in a process chamber are provided herein. The process chamber may be configured to perform any suitable process to a substrate. In some embodiments, the process chamber is configured to perform an etch process, a deposition process, or a preclean process. The process chamber includes a substrate support to support the substrate. A process kit is disposed about the substrate support and includes an upper shield that advantageously is configured to shield chamber components from unwanted materials and is configured to act as a showerhead to provide one or more process gases to a processing volume between the upper shield and the substrate support. As described in greater detail below, the upper shield is also configured to be heated to reduce accumulation of the unwanted materials and reduce the quantity of larger particles during substrate processing which can thereby reduce chamber downtime and provide higher substrate processing throughput.

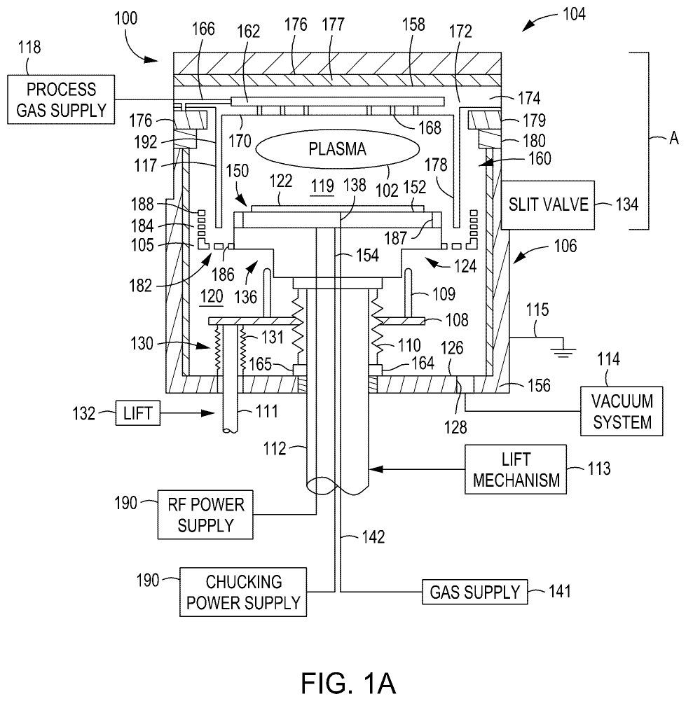

FIG. 1A depicts a schematic side view of a process chamber 100 (e.g., a plasma processing chamber) in accordance with at least some embodiments of the present disclosure. In some embodiments, the process chamber 100 may be configured as a preclean processing chamber. However, other types of process chambers configured for different processes can also use or be modified for use with embodiments of the process kit described herein.

In some embodiments, and as shown in FIG. 1A, the process chamber 100 may be a vacuum chamber which is suitably adapted to maintain sub-atmospheric pressures within an interior volume 120 during substrate processing. In some embodiments, the process chamber 100 can maintain a pressure of about 1.0 mTorr to about 25.0 mTorr. The process chamber 100 may include a chamber body 106 having a sidewall 156 covered by a lid 104 which encloses a processing volume 119 located in the upper portion of the interior volume 120. In some embodiments, an lower liner 180 may rest on the sidewall 156 of the chamber body 106 between the chamber body 106 and the lid 104. The chamber body 106 and the lower liner 180 may be made of metal, such as aluminum. The chamber body 106 may be grounded via a coupling to ground 115.

A substrate support 124 may be disposed within the interior volume 120 to support and retain a substrate 122, such as a semiconductor wafer, for example, or other such substrate. In some embodiments, and as shown in FIG. 1A, the substrate support 124 may generally comprise a pedestal 136 and a hollow support shaft 112 for supporting the pedestal 136. In some embodiments, and as shown in FIG. 1A, the pedestal 136 may include an electrostatic chuck 150 having one or more chucking electrodes embedded therein. In some embodiments, the electrostatic chuck 150 may comprise a dielectric plate. The hollow support shaft 112 may provide a conduit to provide, for example, backside gases, process gases, fluids, coolants, power, or the like, to the electrostatic chuck 150. In some embodiments, and as shown in FIG. 1A, the substrate support 124 may include an edge ring 187 disposed about the electrostatic chuck 150 to enhance process uniformity at an edge of the substrate 122. In some embodiments, the edge ring 187 may be made of alumina (Al₂O₃). A slit valve 134 may be coupled to the chamber body 106 to facilitate transferring the substrate 122 into and out of the interior volume 120.

In some embodiments, the hollow support shaft 112 may be coupled to a lift mechanism 113, such as an actuator or motor, which provides vertical movement of the electrostatic chuck 150 between an upper, processing position, and a lower, transfer position. A bellows assembly 110 may be disposed about the hollow support shaft 112 and may be coupled between the electrostatic chuck 150 and a bottom surface 126 of the process chamber 100 to provide a flexible seal that allows vertical motion of the electrostatic chuck 150 while reducing or preventing loss of vacuum from within the process chamber 100. The bellows assembly 110 may also include a lower bellows flange 164 in contact with an o-ring 165 or other suitable sealing element which contacts the bottom surface 126 to help prevent loss of chamber vacuum.

A substrate lift 130 may include lift pins 109 mounted on a platform 108 connected to a shaft 111 which is coupled to a second lift mechanism 132 for raising and lowering the substrate lift 130 so that the substrate 122 may be placed on or removed from the electrostatic chuck 150. The electrostatic chuck 150 may include through-holes to receive the lift pins 109. A bellows assembly 131 is coupled between the substrate lift 130 and bottom surface 126 to provide a flexible seal which maintains the chamber vacuum during vertical motion of the substrate lift 130.

The hollow support shaft 112 provides a conduit for coupling a backside gas supply 141, a chucking power supply 140, and a RF power supply 190 to the electrostatic chuck 150. In some embodiments, the chucking power supply 140 provides DC power to the electrostatic chuck 150 via conduit 154 to retain the substrate 122. In some embodiments, RF energy supplied by the RF power supply 190 may have a frequency of about 10 MHz or greater. In some embodiments, RF energy supplied by the RF power supply 190 may be provided at a plurality of frequencies. In some embodiments, the RF power supply 190 may have a frequency of about 13.56 MHz and 60 MHz.

In some embodiments, the backside gas supply 141 is disposed outside of the chamber body 106 and supplies gas to the electrostatic chuck 150. In some embodiments, the electrostatic chuck 150 may include a gas channel 138 extending from a lower surface of the electrostatic chuck 150 to an upper surface 152 of the electrostatic chuck 150. The gas channel 138 may be configured to provide backside gas, such as nitrogen (N), argon (Ar), or helium (He), to the upper surface 152 of the electrostatic chuck 150 to act as a heat transfer medium. The gas channel 138 is in fluid communication with the backside gas supply 141 via gas conduit 142 to control the temperature and/or temperature profile of the substrate 122 during use. For example, the backside gas supply 141 can supply gas to cool the substrate 122 during use.

In some embodiments and as shown in FIG. 1A, the process chamber 100 may include a process kit 160 circumscribing various chamber components to prevent unwanted reaction between such components and etched material and other contaminants. The process kit 160 may include includes an upper shield 117 and a lower shield 105.

The upper shield 117 may include a top plate 172 having a top side 158 and a bottom side 170. The upper shield 117 may be made of metal, such as aluminum. In some embodiments, the upper shield 117 may rest on, or otherwise be supported by, the lower liner 180 or sidewall 156 of the chamber body 106. The top plate 172 includes a plenum 162. A channel 166 extends from an outer portion of top plate 172 to the plenum 162. A plurality of holes 168 extend from the plenum 162 to the bottom side 170 of the top plate 172. A process gas supply 118 is coupled to the channel 166 to provide one or more process gases to the interior volume 120 through the channel 166, plenum 162, and plurality of holes 168. In some embodiments, the upper shield 117 may include a tubular body 178 extending down from the bottom side 170 of the top plate 172 and surrounding the plurality of holes 168. When present, the tubular body 178 is configured to surround the substrate support 124. In some embodiments, and as shown in FIG. 1A, the tubular body 178 has an outer side 192 and the top plate 172 has a flange 174 extending outward beyond the outer side 192.

A gas flow path may extend from the channel 166, through the plurality of holes 168, and into the processing volume 119. In some embodiments, the gas flow path may extend from the channel 166, through the plurality of holes 168, and into the processing volume 119 within the tubular body 178. In some embodiments, the gas flow path extends from the process gas supply 118 to the upper shield 117 through the lower liner 180. In some embodiments, and as shown in FIG. 1A, the gas flow path extends from the process gas supply 118 to the upper shield 117 without extending through the lower liner 180. In some embodiments, the process gas supply 118 provides argon (Ar) gas.

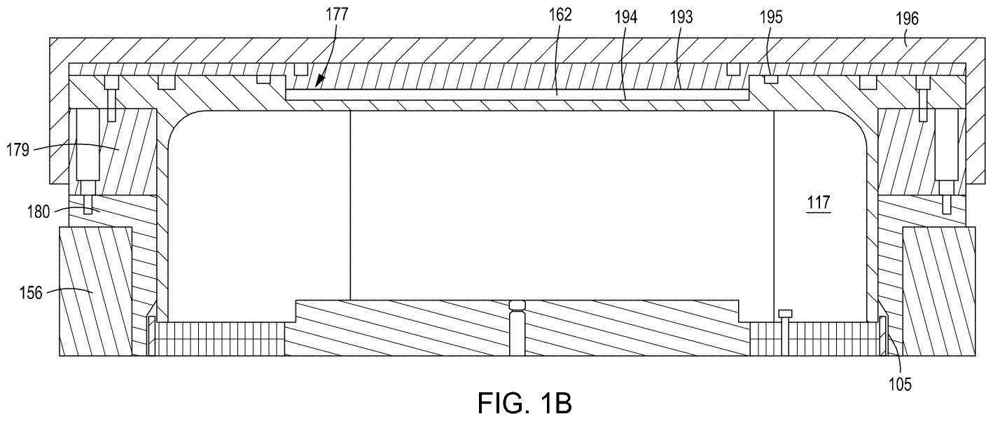

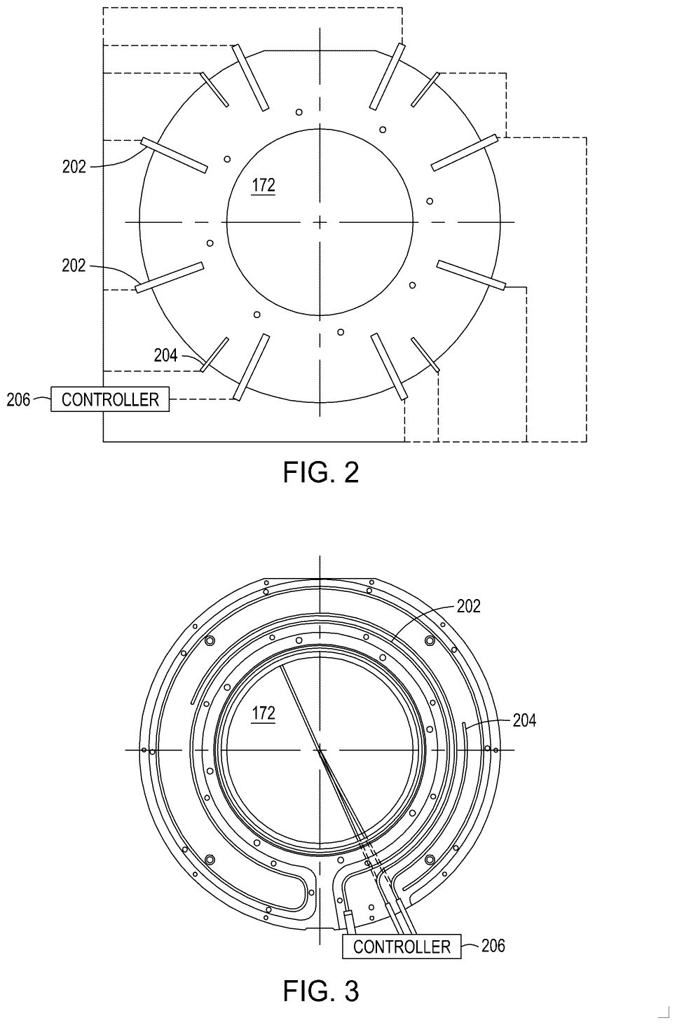

In some embodiments, and as shown in FIGS. 2-3, the process kit 160 may include at least one heater 202 disposed on or embedded in the top plate 172 and at least one temperature sensor 204 disposed on or embedded in the top plate 172. The at least one heater 202 is configured to actively heat the top plate 172 of the process kit 160. The heating of the top plate 172 may also actively heat the tubular body 178. As used herein, “actively heat” refers to controlling the operation of the at least one heater 202 to heat the process kit 160 independently of processing (e.g., plasma processing) occurring in the processing volume 119. Actively heat may be contrasted with “passively heat” which refers to any heating of the process kit 160 that may occur by the heat generated as a byproduct of the processing (e.g., plasma processing) occurring in the processing volume 119.

In some embodiments, and as shown in FIG. 2, the at least one heater 202 may include a plurality of heaters 202 (eight heaters 202 are shown in FIG. 2) spaced about the top plate 172. The heaters 202 may be resistive heaters or heating elements, such as cartridge heaters or trace heaters. In some embodiments and as shown in FIG. 3, the at least one heater 202 includes a single resistive heating element extending about the top plate 172.

The at least one temperature sensor 202 may be used to monitor the temperature of the top plate 172. In some embodiments, and as shown in FIG. 2, the at least one temperature sensor 204 may include a plurality of temperature sensors 204 (four are shown) spaced about the top plate 172. In some embodiments, and as shown in FIG. 2, at least one temperature sensor 204 is spaced between adjacent heaters 202 (i.e., spaced between adjacent resistive heaters). In some embodiments, and as shown in FIG. 2, at least one of the heaters 202 or the temperature sensors 204 extends radially with respect to a center of the top plate 172. In some embodiments, and as shown in FIG. 3, the at least one temperature sensor 204 (two are shown) may extending parallel to the resistive heating element of the heater 202.

In some embodiments, and as shown in FIGS. 2 and 3, a controller 206 may be coupled to the at least one heater 202 and the at least one temperature sensor 204 and the controller 206 may provide feedback control to control output of the heater 202 based on input from the temperature sensor 204. The controller 206 may be any controller capable of providing feedback control to the at least one heater 202.

In some embodiments, and as shown in FIG. 1A, the process kit 160 may include thermal insulation 176 configured to reduce heat dissipation from the heated process kit 160 to the chamber body 106 and the environment. The thermal insulation may include upper thermal insulation 177 and lower thermal insulation 179. In some embodiments, the thermal insulation 176 may extend at least partially along at least one of the top side 158 or the bottom side 170 of the top plate 172. The lower thermal insulation 179 may be disposed below the flange 174. In some embodiments, and as shown in FIG. 1A, the lower thermal insulation 179 may be disposed between the flange 174 and the lower liner 180 and may be formed as a ring. In some embodiments, and as shown in FIG. 1A, the upper thermal insulation 177 may be disposed above the top plate 172 and may be formed as a disc.

In some embodiments, the process kit 160 may be formed of aluminum. In some embodiments, the thermal insulation 176 may include at least one of fiberglass or stainless steel. In some embodiments, the thermal insulation 176 has a lower thermal conductivity than the process kit 160.

In some embodiments, the lower shield 105 circumscribes the substrate support 124. In some embodiments, the lower shield 105 is coupled to a grounded portion of the pedestal 136. In some embodiments, the lower shield 105 is made of metal such as aluminum. In some embodiments, the lower shield 105 may comprise an annular ring 182 that surrounds the substrate support 124 and an annular lip 184 that extends upward from the annular ring 182. In some embodiments, the annular lip 184 may extend substantially perpendicularly from the annular ring 182. In some embodiments, one or more metal straps (not shown) are disposed between the upper shield 117 and the lower shield 105 to advantageously ground the upper shield 117 to a lower shield 105 that is grounded.

The annular ring 182 includes a plurality of ring slots 186 extending through the annular ring 246. In some embodiments, the plurality of ring slots 186 are disposed at regular intervals along the annular ring 182. In some embodiments, the plurality of ring slots 186 includes a plurality of first ring slots and a plurality of second ring slots disposed radially outward of the plurality of first ring slots. In some embodiments, the annular lip 184 includes a plurality of lip slots 188 extending through the annular lip 184. In some embodiments, the plurality of lip slots 188 are disposed at regular intervals along the annular lip 184. In some embodiments, the plurality of lip slots 188 include a plurality of rows, where the plurality of lip slots 188 are arranged along each of the plurality of rows. For example, the plurality of lip slots 188 may include a lower row proximate the annular ring 182, an upper row proximate an upper surface of the annular lip 184, and a central row disposed between the upper row and the lower row.

The plurality of ring slots 186 and the plurality of lip slots 188 are advantageously sized to provide increased conductance therethrough while minimizing plasma leak through the slots. As such, the plurality of ring slots 186 are sized based on pressure in the interior volume 120, temperature in the interior volume 120, and a frequency of the RF power provided to the process chamber 100, for example via RF power supply 190. A pump port 128 is configured to facilitate removal of particles from the interior volume 120 through the plurality of ring slots 186 and the plurality of lip slots 188 of the lower shield 105.

The process chamber 100 is coupled to and in fluid communication with a vacuum system 114 which includes a throttle valve (not shown) and pump (not shown) which are used to exhaust the process chamber 100. In some embodiments, the vacuum system 114 is coupled to the pump port 128 disposed on the bottom surface 126 of the chamber body 106. The pump port 128 facilitates removal of particles from the interior volume 120 through a gap between the upper shield 117 and the substrate support 124. The pressure inside the process chamber 100 may be regulated by adjusting the throttle valve and/or vacuum pump. In some embodiments, the pump has a flow rate of about 1900 liters per second to about 3000 liters per second.

FIG. 1B is a detailed partial view of portion A of FIG. 1A. In some embodiments and as shown in FIG. 1B, the upper thermal insulation 177 may be disc shaped and may have the same size (e.g., diameter) as the top plate 172. The upper thermal insulation 177 may have a central lower protrusion 193 that extends into a central recess 194 in the top side 158 of the top plate 172. The central recess 194 and the central lower protrusion 193 may define the plenum 162. A groove 195 may surround the plenum 162 to receive a sealing member, such as an o-ring or gasket. The groove 195 is configured to receive an o-ring or gasket (not shown) configured to provide a seal around the plenum 162 between the upper thermal insulation 177 and the top side 158 of the top plate 172. Although shown in the top plate 172, the groove 195 can be partially or completely formed in the upper thermal insulation 177. A lid 196 may extend across and cover the upper thermal insulation 177 and may extend down and cover the upper thermal insulation 177, the flange 174, and the lower thermal insulation 179. The lid 196 may be made from a metal, such as stainless steel.

In some embodiments, and as shown in FIG. 1B, the lower thermal insulation 179 may be ring shaped and may be disposed on or coupled to the lower liner 180. In some embodiments, the lower thermal insulation 179 can be spaced (e.g., radially) from the outer side 192 of the tubular body 178.

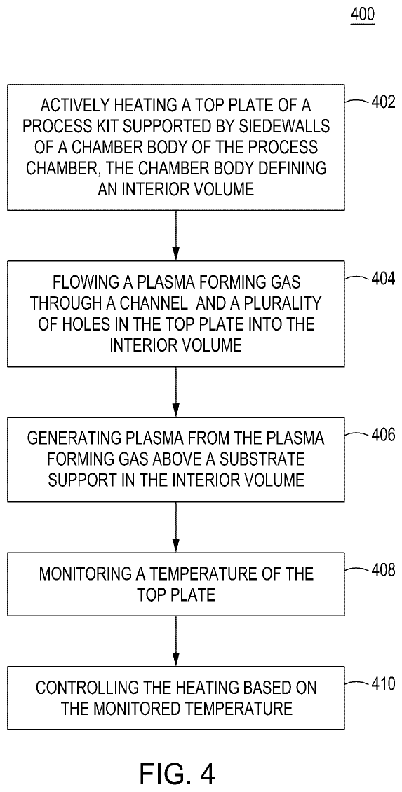

FIG. 4 is a flow chart depicting a method 400 of processing a substrate in a process chamber, such as the process chamber 100, according to some embodiments of the present disclosure. At block 402, the method may include actively heating a top plate (e.g., top plate 172) of a process kit (e.g., process kit 160) supported by sidewall (e.g., sidewall 156) of a chamber body (e.g., chamber body 106) of the process chamber (e.g., process chamber 100), which at least partially defines an interior volume. As discussed above, actively heating may include using the at least one heater 202 to heat the top plate 172. The top plate 172 may be actively heated to maintain a temperature of the top plate 172 of 40° C. to 150° C. If the temperature is maintained less than 40° C., the amount of particles having a size that exceeds a threshold size may be too high to continue with substrate processing such that additional cleaning of the process kit 160 may be performed before resumption of substrate processing. Also, if the temperature is maintained above 150° C., pressure in the interior volume 120 may become too high and cause leakage through seals, such as a vacuum leaks through o-rings between one or more components of the chamber body 106.

At block 404, the method 400 may include flowing a plasma forming gas through a channel (e.g., channel 166) and a plurality of holes (e.g., holes 168) in the top plate into the interior volume. In some embodiments, the top plate 172 may be disposed directly opposite the substrate support 124 and extend across the entire substrate support 124, and the plasma forming gas may enter the interior volume through the plurality of holes disposed on the bottom side 170 of the top plate 172. At block 406, the method 400 may include generating plasma from the plasma forming gas above a substrate support 124 in the interior volume. In operation, for example, a plasma 102 may be created in the interior volume 120 to perform one or more processes. The plasma 102 may be created by coupling power from a plasma power source (e.g., RF power supply 190) to a process gas via the electrostatic chuck 150 to ignite the process gas and create the plasma 102. The RF power supply 190 is also configured to attract ions from the plasma towards the substrate 122. The upper shield 117 is configured to confine the plasma 102 during use. At block 408, the method may include monitoring a temperature of the top plate 172. At block 410, the method 400 may include controlling the heating based on the monitored temperature.

In some embodiments, the entire surface of the top plate 172 may be configured as a single heating zone so that, in the embodiment shown in FIG. 2, for example, each of the plurality of heaters 202 may be controlled to maintain the same temperature throughout the single zone. In some embodiments, the top plate 172 may be divided into multiple heating zones so that each heating zone may be controlled to maintain a temperature independent of the other zones. For example, in some embodiments, in FIG. 2 the top plate 172 may be divided conceptually into four quadrants with each quadrant being a heating zone where each heating zone may be controlled by two heaters and one temperature sensor. The heaters 202 in each quadrant may be independently controlled by one or more controllers 206 based on the temperature sensed by the temperature sensor 204 in the quadrant.

The active heating provides an unexpected reduction in the quantity of particles that flake off the process kit 160 during substrate processing. For example, a preclean process to remove polymer from a substrate was performed using a chamber configured in accordance with aspects of the present disclosure. One hundred substrates were processed with the heaters turned off and eighty substrates were processed using the heaters. After processing one hundred substrates using the heaters, there was a 92% decrease in the number of particles greater than 1 μm. As a second example, a preclean process to remove silicon nitride from a substrate was performed using a chamber configured in accordance with aspects of the present disclosure. Six hundred substrates were processed with the heaters turned off and six hundred substrates were processed using the heaters. After processing six hundred substrates using the heaters, there was a 96% decrease in the number of particles greater than 1 μm.

A heated process kit in accordance with the present disclosure may limit buildup of deposits on the process kit. As a result, less downtime may be needed for preventive maintenance and cleaning of the process kit, which may improve processing throughput. Also, the heated process kit may provide unexpected large reduction in unwanted particle generation to thereby improve cleaning effectiveness and product quality.

While the foregoing is directed to embodiments of the present disclosure, other and further embodiments of the disclosure may be devised without departing from the basic scope thereof.

1. A process kit for use in a process chamber, comprising:
a top plate having a top side and a bottom side;
a plurality of holes disposed on the bottom side;
a channel extending from an outer portion of the top plate and coupled to the plurality of holes;
at least one heater embedded in the top plate; and
at least one temperature sensor embedded in the top plate, wherein a gas flow path extends from the channel, through the plurality of holes, and into an interior volume of the process chamber.

2. The process kit of claim 1, wherein the at least one heater includes a plurality of heaters spaced about the top plate.

3. The process kit of claim 1, wherein the at least one temperature sensor includes a plurality of temperature sensors spaced about the top plate.

4. The process kit of claim 1, further comprising thermal insulation extending at least partially along at least one of the top side or the bottom side of the top plate.

5. The process kit of claim 4, wherein the thermal insulation is configured as a ring or a disc.

6. The process kit of claim 4, wherein the thermal insulation has a lower thermal conductivity than the process kit.

7. The process kit of claim 1, further comprising a tubular body extending down from the bottom side of the top plate and surrounding the plurality of holes, the tubular body further configured to surround a substrate support.

8. The process kit of claim 1, wherein the process kit is made of aluminum.

9. A process chamber, comprising:
a chamber body having a sidewall, the chamber body partially defining an interior volume;
a substrate support disposed in the interior volume;
a process kit supported by the sidewall the process kit comprising:
a top plate having a top side and a bottom side;
a plurality of holes disposed on the bottom side;
a channel extending from an outer portion of the top plate and coupled to the plurality of holes;
at least one heater embedded in the top plate; and
at least one temperature sensor embedded in the top plate, wherein a gas flow path extends from the channel, through the plurality of holes, and into the interior volume.

10. The process chamber of claim 9, further comprising a lower shield comprising and annular ring configured to surround the substrate support and an annular lip extending from an upper surface of the annular ring, wherein the annular ring includes a plurality of ring slots, and wherein the annular lip includes a plurality of lip slots.

11. The process chamber of claim 9, wherein the at least one heater includes a resistive heating element extending about the top plate and the at least one temperature sensor includes a temperature sensing element extending parallel to the resistive heating element.

12. The process chamber of claim 9, wherein the at least one heater includes a plurality of resistive heaters spaced about the top plate,
wherein the at least one temperature sensor includes a plurality of temperature sensors spaced about the top plate, and
wherein at least one temperature sensor is spaced between adjacent resistive heaters.

13. The process chamber of claim 12, wherein at least one of the resistive heaters or the temperature sensors extends radially with respect to a center of the top plate.

14. The process chamber of claim 9, wherein the at least one temperature sensor includes a plurality of temperature sensors spaced about the top plate.

15. The process chamber of claim 9, further comprising thermal insulation extending at least partially along the top side and the bottom side of the top plate.

16. The process chamber of claim 15, wherein the process kit further comprises a tubular body extending down from the bottom side of the top plate and surrounding the plurality of holes, the tubular body further configured to surround a substrate support, and wherein the tubular body has an outer side and the top plate has a flange extending outward beyond the outer side, and wherein the thermal insulation is at least partially disposed below the flange.

17. A method of processing a substrate in a process chamber comprising, the method comprising:
actively heating a top plate of a process kit supported by sidewalls of a chamber body of the process chamber, the chamber body defining an interior volume;
flowing a plasma forming gas through a channel and a plurality of holes in the top plate into the interior volume; and
generating plasma from the plasma forming gas above a substrate support in the interior volume.

18. The method of claim 17, wherein the top plate is disposed directly opposite the substrate support and extends across the entire substrate support, and wherein the plasma forming gas enters the interior volume through the plurality of holes disposed on a bottom side of the top plate.

19. The method of claim 18, wherein the plurality of holes are located around the substrate support.

20. The method of claim 18, further comprising:
monitoring a temperature of the top plate; and
controlling the heating based on the monitored temperature.
